(19) United States
(12) Patent Application Publication
(10) Pub. No.: US 2005/0245015 A1
(43) Pub. Date: Nov. 3, 2005

(54) Method for manufacturing a semiconductor device having a dual-gate structure

(75) Inventor: Masahiko Ohuchi, Tokyo (JP)

Correspondence Address: YOUNG & THOMPSON, 745 SOUTH 23RD STREET, 2ND FLOOR, ARLINGTON, VA, 22202, US

(73) Assignee: ELPIDA MEMORY INC., TOKYO (JP)

(21) Appl. No.: 11/116,445

(22) Filed: Apr. 28, 2005

(30) Foreign Application Priority Data
Apr. 28, 2004 (JP) 2004-1333384

(51) Int. Cl. H01L 21/336

(52) U.S. Cl. 438/197; 438/283

(57) ABSTRACT

A method of manufacturing a semiconductor device having a dual-gate structure includes the steps of forming P-type and N-type gate silicon layers in different regions; implanting P-type or N-type impurities into the P-type and N-type gate silicon layers; depositing a metallic film on the P-type and N-type gate silicon layers; patterning the metallic film by using a mask having a gate-electrodes pattern, patterning the P-type and N-type gate silicon layers by the mask and the patterned metallic film to leave P-type and N-type gate silicon electrodes.

### BACKGROUND OF THE INVENTION

1. Field of the Invention

The present invention relates to a method for manufacturing a semiconductor device having a dual-gate structure.

2. Description of the Related Art

A semiconductor device is known having two-conductivity-type gate electrodes, one doped with N-type impurities and the other doped with P-type impurities. This type of the semiconductor device is generally referred to as a dual-gate semiconductor device. The dual-gate structure provides a higher operating speed for the MOS transistors. Thus, the dual-gate structure is employed or is to be employed mainly in semiconductor devices that need to operate at high speeds.

The dual-gate semiconductor device is typically manufactured in the following steps. First, a gate insulating film is formed on a semiconductor substrate. Then, a gate polysilicon layer or a gate amorphous silicon layer (hereinafter, these layers will be collectively referred to as gate silicon layers) is formed on the semiconductor substrate via the gate insulating film. Using a photoresist mask, impurities are introduced into two regions of the gate silicon layer by means of ion implantation, thereby forming an N-type region and a P-type region of the gate silicon layer. A single-layer metallic film, such as WSi film, or a multi-layer metallic film, such as W/WN film, is formed on the N-type region and P-type region. On the metallic film, there is further formed an insulating film made of SiO₂, SiN or the like. Using the insulating film as a hard mask, the metallic film is dry-etched. Then, using the same hard mask together with the patterned metallic film, the gate silicon layer is subjected to an etching process.

FIG. 5 shows a graph representing relations between the impurity concentration and dry-etch rate in semiconductor layers. More precisely, it shows the relation between the phosphorus (P) concentration (atoms/cm³) of a silicon layer and the etch rate (nm/min) thereof, and also relation between the boron (B) concentration of a silicon layer and the etch rate thereof. As understood from FIG. 5, the etch rate scarcely changes with the concentration of boron (B) or phosphorus (P). Nevertheless, the etch rate of the N-type silicon layer containing P is higher than that of the P-type silicon layer containing B. The difference in the etch rate is about 20% to 30%. Such a difference in the etch rate between a P-type silicon layer and an N-type silicon layer is described in, for example, Ogino et al. (Mitsubishi Electric Co., Ltd.), “Precise Evaluation of Pattern Distortion with Variety of Impurity Conductivity”, Dry Process Symposium, 11-6, the Institute of Electrical Engineer of Japan.

FIGS. 6A and 6B, and FIGS. 7 to 9 show possible defects in the dual-gate structures, wherein a P-type silicon layer 204 and an N-type silicon layer 203 are formed on a silicon substrate 201 via a gate insulating film 202, and etched by using a hard mask 206 and a metallic film 205 patterned. In the dual-gate structure, the N-type silicon layer 203 is etched in a larger amount compared to the P-type silicon layer 204 if both the layers 203 and 204 are subjected to dry etching at the same time, because of the above difference in the etch rate. As a result, the width of the N-type silicon layer 203 is made smaller due to side etching thereof, as shown in FIG. 6A, or has a staggered taper with a smaller width in the base portion, as illustrated in FIG. 6B. In either case, the N-type silicon layer 203 has an undesirable etched shape. Further, a part of the gate insulating film 202 which underlies the P-type silicon layer 204 has a larger thickness compared to another part of the gate insulating film 202 which underlies the N-type silicon layer 203.

In another case, as illustrated in FIG. 7, there is a possibility that the etching does not stop at the top surface of the gate insulating film 202, penetrating the gate insulating film 202. If this happens, the etching may also damage the silicon substrate 201.

In order to prevent the N-type silicon layer 203 from having an undesirable shape, the etching time length may be shortened or the etching conditions may be adjusted to prevent the side etching. This may result, however, in a larger width of the P-type silicon layer 204. In such a case, the P-type silicon layer 204 may have a forward taper with a larger width in the base portion, or may have a flare in the base portion, as shown in FIG. 8, resulting in a an undesirable shape. Further, silicon residue may remain on the gate insulating film or other portion.

Further, the P-type silicon layer 204 formed on the gate insulating film 202 may be locally etched in the lateral direction, as shown in FIG. 9, in the vicinity of the interface between the P-type silicon layer 204 and the gate insulating film 202, resulting in an undesirable shape referred to as “undercut”.

To solve the problems described above, the techniques described in Jpn. Pat. Appln. Laid-Open Publication Nos. 2000-021999 and 2000-058511 may be employed. In the technique described in Publication No. 2000-021999, the P-type silicon layer 204 is designed to have a larger thickness than the N-type silicon layer, to thereby solve the above problems. In the technique described in Publication No. 2000-058511, the etching condition is altered, to thereby prevent the damage of the gate insulating film and to diminish the difference in size between the different parts of the gate insulating film.

In the technique described in Publication No. 2000-021999, however, not a few additional steps, such as lithography, silicon CVD and etching, should be performed. This lowers the efficiency of the manufacture of the semiconductor device in economical aspect. In addition, the interconnection layers overlying the gate electrode layer may have an uneven thickness because the gate electrodes formed on the P-type silicon layer and N-type silicon layer differ in terms of thickness. This makes it difficult to form an even-thickness insulating film and to dispose contact plugs between adjacent gate electrodes. Particularly, the technique described in Publication No. 2000-058511 cannot provide gate electrodes having an accurate width.

### SUMMARY OF THE INVENTION

It is an object of the present invention to provide a method for manufacturing a semiconductor device, in which a P-type silicon layer and an N-type silicon layer are patterned to have desired shapes, to thereby solve the problems encountered in the conventional techniques.

The present invention provides a method for manufacturing a semiconductor device including the consecutive steps of: forming consecutively a gate insulating film and a silicon layer on a silicon substrate; forming P-type and N-type silicon layers from the silicon layer; implanting P-type or N-type impurities into the P-type and N-type silicon layers by using an implantation mask having a gate-electrodes pattern; and selectively etching the P-type and N-type silicon layers by using an etching mask having a gate-electrodes pattern to leave P-type and N-type gate electrodes.

In the method of manufacturing the semiconductor device according to the present invention, the P-type impurities or N-type impurities implanted in the P-type silicon layer and the N-type silicon layer by using the implantation mask having a gate-electrodes pattern prevents the defects, such as caused by the side etching, from occurring in the etching step in which the P-type and N-type silicon layers are selectively etched. Hence, the P-type silicon layer and the N-type silicon layer can be patterned to provide a desirable gate electrode pattern.

### BRIEF DESCRIPTION OF THE DRAWINGS

FIGS. 1A to 1H are sectional views showing consecutive steps of a fabrication process for manufacturing a semiconductor device according to a first embodiment of the present invention;

FIG. 2 is a graph showing the relation between the concentration of N-type impurities (P) and the etch rates of the N-type and P-type gate silicon layers additionally implanted by the N-type impurities;

FIG. 3 is a sectional view showing a step in a fabrication process for manufacturing a semiconductor device according to a second embodiment of the present invention;

FIG. 4 is a sectional view showing a step of a fabrication process for manufacturing a semiconductor device according to a third embodiment of the invention;

FIG. 5 is a graph representing the relation between the impurity concentration and the etch rate in dry etching;

FIGS. 6A and 6B are sectional views of semiconductor devices manufactured by using a conventional dual-gate etching process;

FIG. 7 is a sectional view of a semiconductor device manufactured by using a conventional dual-gate etching process;

FIG. 8 is a sectional view of another semiconductor device manufactured by using a conventional dual-gate etching process; and

FIG. 9 is a sectional view of another semiconductor device manufactured by using a conventional dual-gate etching process.

### DETAILED DESCRIPTION OF THE PREFERRED EMBODIMENTS

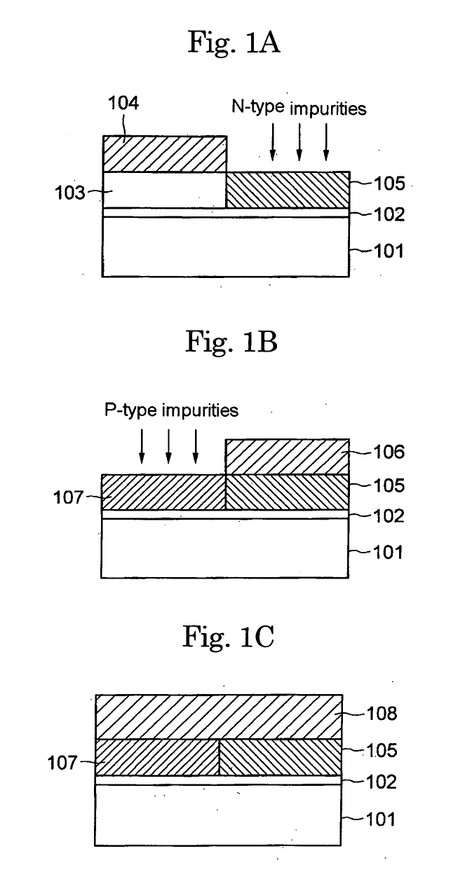

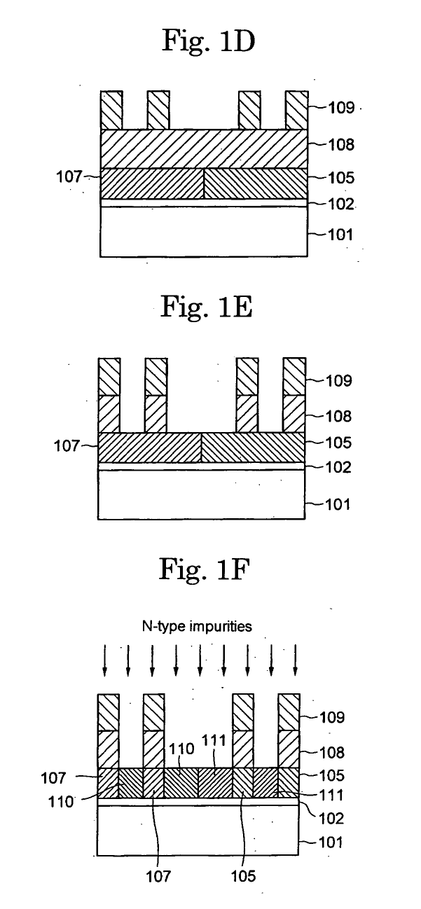

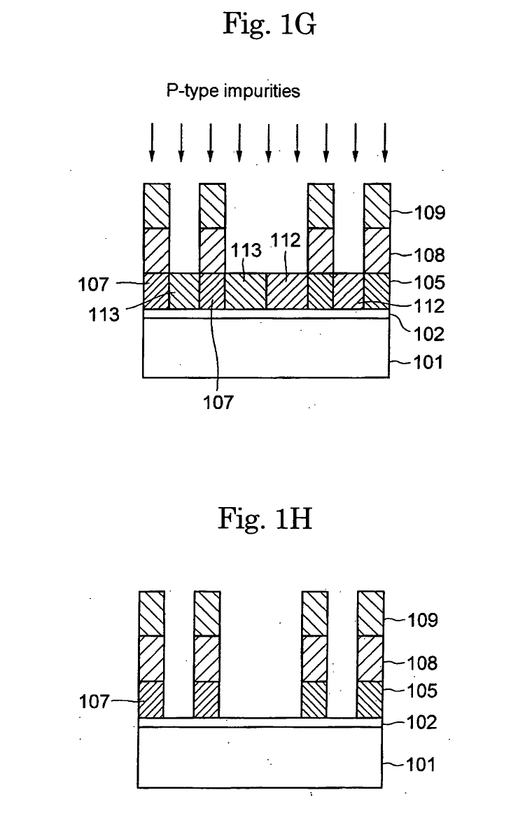

Embodiments of the present invention will be described, with reference to the accompanying drawings, wherein similar constituent elements are designated by similar reference numerals. FIGS. 1A to 1H are sectional views showing consecutive steps of a fabrication process for manufacturing a semiconductor device according to a first embodiment of the present invention. In the first embodiment, a dual-gate etching process is performed to configure each of an N-type silicon layer and a P-type silicon layer in a desired shape. It is to be noted that the method of manufacturing a semiconductor device according to the present invention can be used in manufacture of a high-speed DRAM, an SRAM, a nonvolatile memory, such as a flash memory, and the like, and can configure gate electrodes of transistors in desired structures.

As shown in FIG. 1A, a gate insulating film 102 is formed on a silicon substrate 101 as an underlying layer for the gate electrode layer. Before forming the gate insulation film 102, the silicon substrate 101 is subjected to a variety of process steps such as impurity implantation, etching, polishing and heat treatment. However, the silicon substrate 101 need not necessarily undergo these process steps before forming the gate insulating film 102. The gate insulating film 102 may be formed in, for example, a batch oxidation chamber, a single-wafer oxidizing system or a CVD apparatus. The gate insulating film 102 is made of a material selected from the group of silicon oxide, silicon nitride, silicon oxynitride, a metal oxide such as tantalum oxide, and the like, depending on the characteristics that the transistors having the gate electrodes should have.

After the gate insulating film 102 is formed, a gate silicon layer 103 is formed, over the entire surface of the resultant structure, by means of a CVD technique or the like. A photoresist mask 104 is then formed on the part of the gate silicon layer 103 other than the part of the gate silicon layer 103 in which an N-type region is to be formed. Using the photoresist mask 104 as an implantation mask, N-type impurities are ion-implanted into the part of the gate silicon layer 103 in an N-type implantation process, thereby forming an N-type gate silicon layer 105. The N-type impurities may be P or As, or a compound thereof that releases electrons if substituted for silicon atoms in the silicon crystal.

After the N-type gate silicon layer 105 is formed, the photoresist mask 104 is removed by a process such as plasma removal or an ordinary wet etching process using acid. Thereafter, as show in FIG. 1B, another photoresist mask 106 is formed on the part of the gate silicon layer 103 other than the part thereof, in which a P-type region is to be formed. Using this photoresist mask 106 as an implantation mask, P-type impurities are ion-implanted into the part of the gate silicon layer 103 in an P-type implantation process, thereby forming a P-type gate silicon layer 107. The P-type impurities may be B or a compound thereof such as BF2, that releases holes if substituted for silicon atoms in the silicon crystal.

After the N-type gate silicon layer 105 and P-type gate silicon layer 107 are formed, a metallic film 108 is formed thereon as shown in FIG. 1C, by means of an ordinary CVD or PVD process. The metallic film 108 may be a single-layer film of metal such as W, WN, WSi, Ti, TiN, Pt and Co. Alternatively, the metallic film 108 may be a multi-layer film composed of a plurality of different metallic layers. As shown in FIG. 1D, a hard mask 109 is then formed on the metallic film 108. The hard mask 109 is to be used in the process of forming gate electrodes. The hard mask 109 is formed by etching such as dry etching of a single-layer film such as silicon oxide film, silicon nitride film, silicon oxynitride (SiON) film or amorphous carbon film, formed by, for example, CVD process, or on a multi-layer film composed of these single-layer films, thereby providing a mask of a desired pattern.

After the hard mask 109 is formed, the metallic film 108 is dry-etched by using the hard mask 109 until the N-type gate silicon layer 105 and P-type gate silicon layer 107 are exposed as shown in FIG. 1E. Preferably, this dry etching is performed so that the metallic film 108 has side surfaces as vertical as possible. It is also desired that the dry etching be so performed that the N-type gate silicon layer 105 and P-type gate silicon layer 107 are etched as little as possible. In a concrete example, the N-type gate silicon layer 105 and P-type gate silicon layer 107 should be etched to the depth of about 10 to 30 nm. Otherwise, the metallic film 108 has undesirable side surfaces other than vertical side surfaces.

After the metallic film 108 is processed to expose therefrom parts of the N-type gate silicon layer 105 and P-type gate silicon layer 107, N-type impurities are implanted by using the hard mask 109 and metallic film 108 as implantation masks, as is illustrated in FIG. 1F. It is desired that this implantation of N-type impurities be continued until that part of the P-type gate silicon layer 107, from which the metallic film 108 has been removed (i.e., the part that will be removed later by etching), has an N-type conductivity. The implantation of N-type impurities forms an N⁻-type silicon region 110 in the P-type gate silicon layer 107. In the N-type gate silicon layer 105, an N⁺-type silicon region 111 is formed in the part from which the metallic film 108 has been removed. The N⁺-type silicon region 111 has a higher impurity concentration than the N-type gate silicon layer 105.

P-type impurities may be implanted as shown in FIG. 1I, in place of N-type impurities, by using the hard mask 109 and metallic film 108 as implantation masks. In this case, it is desirable to implant the P-type impurities until that part of the N-type gate silicon layer 105, from which the metallic film 108 has been removed, assumes a P-type conductivity. This implantation of P-type impurities forms a P⁻-type silicon region 112 in the N-type gate silicon layer 105. In the P-type gate silicon layer 107, an P⁺-type silicon region 113 is formed in the part from which the metallic film 108 has been removed. The P⁺-type silicon region 113 has a higher impurity concentration than the P-type gate silicon layer 107.

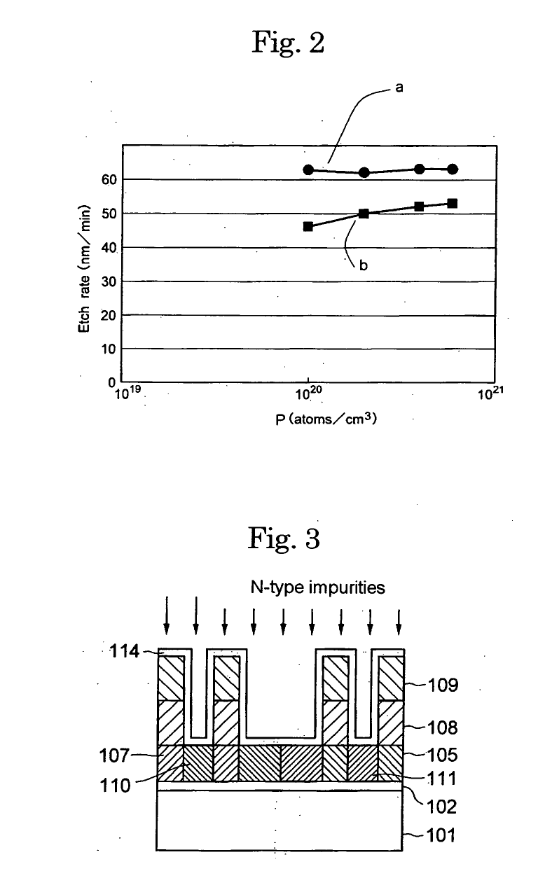

FIG. 2 shows the relation between the amount of N-type impurities implanted and the etch rates of those parts of the N-type and P-type gate silicon layers 105 and 107 (i.e., N⁺-type silicon region 111 and N⁻-type silicon region 110), which are to be removed by etching. Curve “a” represents the etch rate of the N-type gate silicon layer 105 additionally implanted with N-type impurities (P), whereas curve “b” represents the P-type gate silicon layer 107 implanted with N-type impurities (P). It is assumed here that, before the implantation of N-type impurities, P and B are implanted into the N-type gate silicon layer 105 and P-type gate silicon layer 107, respectively, in an amount of 2×10²⁰ atoms/cm³. Then, the conductivity type of that region of the P-type gate silicon layer 107, which will be etched and removed, changes from the P-type to the N-type when the amount of P implanted is increased by the implantation of N-type impurities (P). As understood from FIG. 2, the difference between the etch rate of the N-type gate silicon layer 105 containing N-type impurities implanted and the P-type gate silicon layer 107 containing N-type impurities implanted decreases as the amount of the implanted N-type impurities increases. This phenomenon is also observed when P-type impurities (B) is implanted in a P-type impurity implantation process.

After the N-type impurities or P-type impurities are implanted, dry etching is carried out, using the hard mask 109 as an implantation mask. The N-type gate silicon layer 105 and P-type gate silicon layer 107 are thereby patterned as illustrated in FIG. 1H. This patterning removes the N⁻-type silicon region 110 and N⁺-type silicon region 111. As a result, the N-type gate silicon layer 105 and P-type gate silicon layer 107 assume desired shapes. Thus shaped, the layers 105 and 106 have desired gate-electrode patterns.

In the present embodiment, N-type impurities or P-type impurities are implanted into that region of the N-type gate silicon layer 105, which will be removed, and into that region of the P-type gate silicon layer 107, which will be removed, before the N-type gate silicon layer 105 and P-type gate silicon layer 107 are patterned by means of etching. The difference in the etch rate between the N-type gate silicon layer 105 and P-type gate silicon layer 107 is therefore reduced. This suppresses the undesirable etched profiles such as side etching, taper and the like. Hence, the N-type gate silicon layer 105 and P-type gate silicon layer 107 have vertical side surfaces. Moreover, due to the small difference in the etch rate, a desirable dual-gate etching process, which minimizes the difference in the width between the N-type gate silicon layer 105 and the P-type gate silicon layer 107 and the difference in the thickness between the residual gate insulating films 102 provided in the N-type region and the P-type region, can be performed.

FIG. 3 is a sectional view showing a step of a fabrication process for manufacturing a semiconductor device according to a second embodiment of the present invention. The second embodiment is similar to the first embodiment except that a thin insulating film 114 is formed on the N-type gate silicon layer 105 and P-type gate silicon layer 107 before N-type or P-type impurities are implanted. More specifically, the thin insulating film 114 is formed on those regions of the layers 105 and 107, which will be removed by etching. In the method described below, N-type impurities are implanted into those regions of the N-type gate silicon layer 105 and P-type gate silicon layer 107, which are to be etched. P-type impurities may be implanted, instead. In this case, a similar advantage can be achieved.

In the second embodiment, steps similar to those shown in FIG. 1A to 1E are performed, thereby configuring the metallic film 108 into a desired shape. Then, CVD or a similar process is carried out, thereby forming an insulating film 114, such as a Si₃N₄ film or an SiO₂ film, which is about 3 nm to 20 nm thick, on the entire surface of the resultant structure, as is illustrated in FIG. 3. After the thin insulating film 114 is formed, N-type impurities are implanted through the insulating film 114 into those regions of the N-type gate silicon layer 105 and P-type gate silicon layer 107, which are to be removed by etching. It is desirable to continue implanting of the N-type impurities until that region of the P-type gate silicon layer 107, which will be etched, assumes an N-type conductivity. Thereafter, the N⁻-type silicon region 110, the N⁺-type silicon region 111, and the thin insulating film 114 are removed by etching, in a process similar to the process shown in FIG. 1H. Thus, the N-type gate silicon layer 105 and the P-type gate silicon layer 107 are patterned to have desired shapes.

It is noted that the element, which is ion-implanted as the N-type impurities, may pass through the gate silicon layers 103 and gate insulating film 102 and reach the silicon substrate 101. If this is the case, the characteristics of the transistor change undesirably, thereby causing a possibility that the semiconductor device does not operate normally. In the present embodiment, the thin insulating film 114 is formed on those regions of the N-type gate silicon layer 105 and the P-type gate silicon layer 107, which will be removed by etching, and N-type impurities are implanted through the thin insulating film 114. Thus, the element, i.e., the N-type impurities are prevented from passing through the gate silicon layers 103 or the gate insulating film 102. The second embodiment achieves other advantages that are similar to those of the first embodiment.

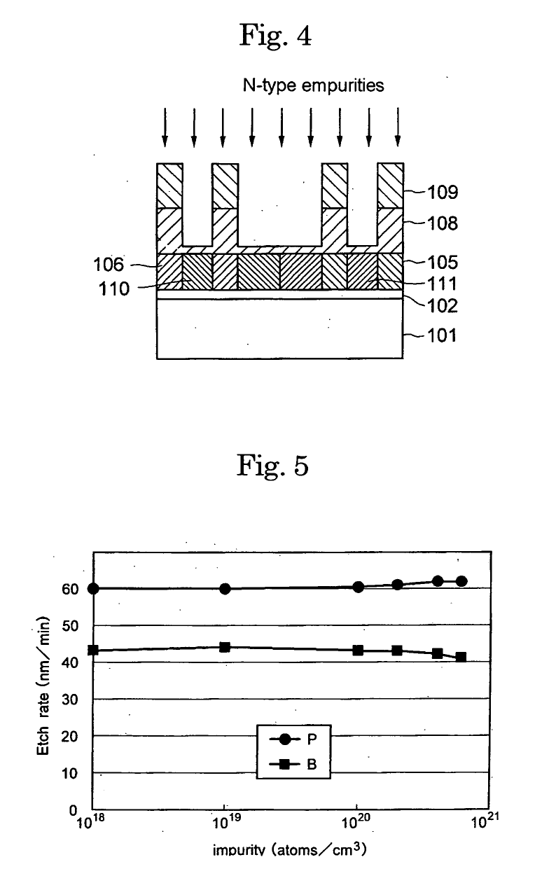

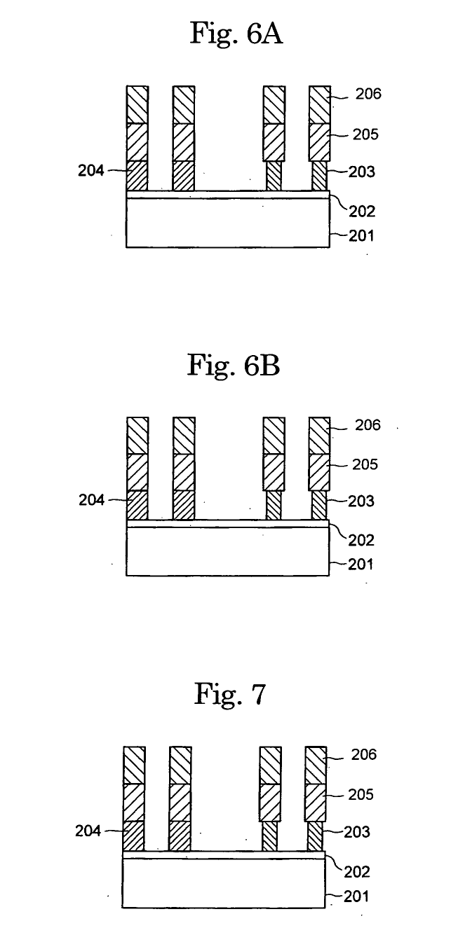

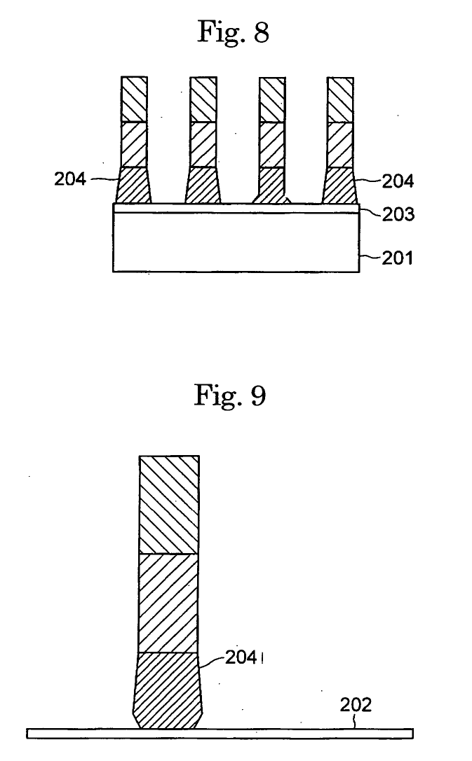

FIG. 4 is a sectional view showing a step of a fabrication process for manufacturing a semiconductor device according to a third embodiment of the present invention. In the present embodiment, N-type impurities or P-type impurities are implanted into those regions of the N-type gate silicon layer 105 and P-type gate silicon layer 107, which are to be removed by etching, with a part of metallic film 108 remaining on the regions of the N-type and P-type gate silicon layers 105 and 107. In the method described below, the N-type impurities are implanted into those regions of the N-type gate silicon layer 105 and P-type gate silicon layer 107, which is to be etched. P-type impurities may be implanted, instead. In this case, a similar advantage will be achieved.

In the third embodiment, steps similar to those shown in FIG. 1A to 1D are performed, thereby forming a hard mask 109 on the metallic film 108. After the hard mask 109 is thus formed, etching is performed on the metallic film 108, thereby configuring the metallic film 108 into a desired shape. The etching is carried out so that those parts of the metallic film 108, which overlie the N-type gate silicon layer 105 and P-type gate silicon layer 107 are not completely removed, as is illustrated in FIG. 4. In other word, residual parts of metallic film 108 are left on the N-type silicon layer 110 and the N⁺-type silicon layer 111.

The metallic film 108 is etched for an estimated etching time length T, after which those parts of the metallic film 108, which remain on the N-type silicon layer 110 and N⁺-type silicon layer 111, are about 5 to 20 nm thick, so long as the metallic film 108 is composed of a single-metallic film. To be more specific, the etching time length T is represented by the following relationship:
T=(X−Z)×(Y)/(X)
where X is the thickness (nm) of the metallic film 108, Y is the time length (sec) from the emission of plasma to the end of etching, and Z is the thickness (nm) that the residual parts of the metallic film 108 should have.

The metallic film 108 may be made of WSi and have a light-transmittance property. In this case, the residual parts of the metallic film 108 are monitored for the thickness thereof by using the interference of light. When the thickness of each residual part reaches a desired value, the etching is terminated. Thus, the thickness of the residual parts of the metallic film 108 can be adjusted to about 5 to 20 nm.

The metallic film 108 may be a multi-layer film instead of the single-layer film. If this is the case, the etching of the metallic film 108 may be terminated at the interface between two adjacent layers of the metallic film 108 as will be described below. It is assumed here that the metallic film 108 is composed of a top layer made of W and a bottom layer made of WN or TiN. In this case, only the top layer, i.e., the W layer, is etched, and the bottom layer, i.e., the WN or TiN layer, is not etched substantially at all.

If the top layer and the bottom layer are made of W and WN, respectively, an ordinary dry-etching system having therein an induction coil is used, performing the etching in the conditions of: SF₆ (or NF₃)=20 sccm; N₂=50 sccm; Cl₂=70 sccm; ambient pressure of 3 mT; plasma power of 700 W; bias power of 30 W; and stage temperature of 20 degrees C. In these conditions, N₂ should be added to the gas system that contains F in order to adjust the etch rate of W to at least 1.5 times the etch rate of WN. If the top layer and the bottom layer are made of W and TiN, respectively, the ordinary dry-etching system having an induction coil is also used, thereby performing the etching in the conditions of: SF₆ (or NF₃)=50 sccm; N₂=50 sccm; ambient pressure of 3 mT; plasma power of 700 W; bias power of 30 W; and stage temperature of 20 degrees C.

After the metallic film 108 is etched, N-type impurities are implanted through the residual parts of the metallic film 108, into those regions of the N-type gate silicon layer 105 and P-type gate silicon layer 107, which are to be removed by etching. It is desirable to continue implanting of the N-type impurities until that part of the P-type gate silicon layer 107, from which the metallic film 108 is to be removed has an N-type conductivity. Thereafter, a step similar to the step shown in FIG. 1H is carried out, thereby removing the N⁻-type silicon region 110, the N⁺-type silicon region 111, and the residual parts of the metallic film 108. Thus processed, the N-type gate silicon layer 105 and the P-type gate silicon layer 107 assume desired shapes.

In the present embodiment, N-type impurities are implanted through the residual parts of the metallic film 108. This prevents the elements and the like, which are introduced as the N-type impurities, from passing through the gate silicon layer 103 and the gate insulating film 102 to reach the silicon substrate 101, without then need for forming a thin insulating film such as 114 in FIG. 5. The residual parts of the metallic film 108 can be provided by, for example, adjusting the time length for etching the metallic film 108. Therefore, this embodiment can achieve an advantage similar to that of the second embodiment, without performing any additional steps. The other advantages of this embodiment are similar to those of the first embodiment.

It is assumed here that the dry-etching system is a plasma apparatus that has an induction coil, although another high-density plasma apparatus that uses microwaves or UHF waves, or an ECR apparatus, may be employed instead. The dry-etching conditions specified above are mere exemplified ones. They can be changed, if necessary, depending on the type of the etching apparatus and the composition of the metallic film 108. The metallic film 108 may be made of metals other than W, WN, TiN, WSi, Ti, TiN, Pt and Co described above. In the embodiments described above, the N-type gate silicon layer 105 is first formed (FIG. 1A) and the P-type gate silicon layer 107 is then formed (FIG. 1B). Instead, these layers may be formed in the reverse order.

Since the above embodiments are described only for examples, the present invention is not limited to the above embodiments and various modifications or alterations can be easily made therefrom by those skilled in the art without departing from the scope of the present invention.

1. A method for manufacturing a semiconductor device comprising the consecutive steps of:
forming consecutively a gate insulating film and a silicon layer on a silicon substrate;
forming P-type and N-type silicon layers from said silicon layer;
implanting P-type or N-type impurities into said P-type and N-type silicon layers by using an implantation mask having a gate-electrodes pattern; and
selectively etching said P-type and N-type silicon layers by using an etching mask having a gate-electrodes pattern to leave P-type and N-type gate electrodes.

2. The method according to claim 1, further comprising, between said P-type and N-type silicon layers forming step and said implanting step, the steps of:
depositing a metallic film on said P-type and N-type silicon layers; and
patterning said metallic film by selectively etching using said implantation mask.

3. The method according to claim 2, wherein said patterning step is such that said metallic film patterned exposes therefrom parts of said P-type and N-type silicon layers.

4. The method according to claim 3, further comprising, between said patterning step and said implanting step, the step of depositing an insulating layer on said patterned metallic film and said parts of said P-type and N-type silicon layers.

5. The method according to claim 4, wherein said insulating layer includes one of silicon oxide, silicon nitride, silicon oxynitride and a metal oxide.

6. The method according to claim 4, wherein said insulating layer is 3 to 20 nm thick.

7. The method according to claim 2, wherein said patterning step is such that said metallic film patterned does not expose therefrom said P-type and N-type silicon layers.

8. The method according to claim 7, wherein said metallic film includes a plurality of different metallic layers, and said patterning step is stopped at an interface between adjacent two of said metallic layers.

9. The method according to claim 1, wherein said implanting step implants a P-type impurity element having a pentavalent, or a compound thereof.

10. The method according to claim 1, wherein said implanting step implants an N-type impurity element having a trivalent, or a compound thereof.

11. The method according to claim 1, wherein said implanting step implants P-type impurities until said N-type silicon layer assumes a P-type conductivity.

12. The method according to claim 1, wherein said implanting step implants N-type impurities until said P-type silicon layer assumes an N-type conductivity.

13. The method according to claim 1, wherein said implantation mask and said etching mask uses a common mask.
